(19) United States
(12) Patent Application Publication
(10) Pub. No.: US 2025/0252993 A1
(43) Pub. Date: Aug. 7, 2025

(54) FAR-END BIT LINE PRE-CHARGE FOR HIGH-DENSITY SRAMS

(71) Applicant: Taiwan Semiconductor Manufacturing Company Ltd., Hsinchu (TW)

(72) Inventors: Venkateswara Reddy KONUDULA, Hsinchu (TW); Nikhil PURI, Hsinchu (TW); Teja MASINA, Hsinchu (TW); Kao-Cheng LIN, Hsinchu (TW); Yen-Huei CHEN, Hsinchu (TW); Hung-Jen LIAO, Hsinchu (TW)

(73) Assignee: Taiwan Semiconductor Manufacturing Company Ltd., Hsinchu (TW)

(21) Appl. No.: 18/434,326

(22) Filed: Feb. 6, 2024

(51) Int. Cl. G11C 11/418; G11C 11/412; G11C 11/419

(52) U.S. Cl. CPC G11C 11/418; G11C 11/412; G11C 11/419

(57) ABSTRACT

A memory circuit includes a memory array comprising a first portion comprising a plurality of first memory cells, and a second portion comprising a plurality of second memory cells. The memory circuit includes an input/output (I/O) circuit physically disposed next to the memory array along a first lateral direction. The I/O circuit is operatively coupled to the first portion and the second portion through a first access line and a second access line, respectively. The memory circuit includes a first pre-charge circuit physically disposed opposite the first portion from the I/O circuit, and configured to charge the first access line prior to accessing the first memory cells. The memory circuit includes a second pre-charge circuit physically disposed opposite the second portion from the first pre-charge circuit, and configured to charge at least a portion of the second access line prior to accessing the second memory cells.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure should be understood from the following detailed description with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory device, in accordance with various embodiments.

FIG. 2 illustrates a block diagram of the memory device of FIG. 1 including far-end bit line pre-charge circuits, in accordance with various embodiments.

FIG. 3 illustrates a schematic diagram of a first example far-end bit line pre-charge circuit of FIG. 2, in accordance with various embodiments.

FIG. 4 illustrates a schematic diagram of a second example far-end bit line pre-charge circuit of FIG. 2, in accordance with various embodiments.

FIG. 5 illustrates a schematic diagram of a third example far-end bit line pre-charge circuit of FIG. 2, in accordance with various embodiments.

FIG. 6 illustrates a schematic diagram of a fourth example far-end bit line pre-charge circuit of FIG. 2, in accordance with various embodiments.

FIG. 7 illustrates a schematic diagram of a fifth example far-end bit line pre-charge circuit of FIG. 2, in accordance with various embodiments.

FIG. 8 illustrates a schematic diagram of a sixth example far-end bit line pre-charge circuit of FIG. 2, in accordance with various embodiments.

FIG. 9 illustrates a flow of an example method for forming a memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As integrated circuit technology advances, it may be desired to optimize memory density for scaling to lower technology nodes. With static random access memory (SRAM) occupying a relatively large portion of the system-on-chip (SOC) area, e.g., approximately 70% in certain systems or applications, the circuits, architectures, or floorplans may be designed, maintaining or augmenting area efficiency. The emphasis on area efficiency can be particularly crucial in the context of applications dominated by SRAM. Furthermore, achieving a reduction in occupied areas, further to enhancing the overall area efficiency, can contribute to a consequential decrease in capacitance. The reduction in capacitance, in turn, may lead to a decrease in dynamic power consumption. Thus, these interrelated aspects underscore the intricacies of semiconductor technology as it pertains to memory density, area efficiency, and power consumption at lower technology nodes.

In some scenarios, the memory density can be improved by the reduction of periphery allocated to a specified bitcell array size. This approach can optimize the spatial utilization of the integrated circuit, contributing to improved overall efficiency. In some cases, the periphery may be reduced by utilizing the maximum number of bitcells per bit line (BL) supported by the systems in consideration of Ion/Ioff ratio. In some configurations, extending the density optimization paradigm may involve the utilization of the fly-bit line (FBL) architecture, as discussed herein.

For example, in certain systems, there may be a notable increase in BL resistance in advanced technology nodes. The increase in the BL resistance may be of particular concern when maximizing the number of rows per BL, such as on at least one of the actual BLs and on FBLs. The heightened BL resistance, compounded by an augmented number of cells per BL, can pose challenges in pre-charging the BL. For instance, due to the relatively higher BL resistance and augmented number of cells per BL, it may take an excessive amount of time to achieve pre-charge onto the BLs at the far end (e.g., the end of the BL opposite to the input/output (I/O) circuit. In certain situations, the excessive time consumption for pre-charging the BL at the far end may be exacerbated in consideration of the FBL architecture. Additionally, owing to voltage drop across relatively long/extensive BLs, any disparity in pre-charge levels between BL and a complementary BL (e.g., bit line B (BLB)) may introduce functional issues during certain memory operations (e.g., read operation) as the differential is affected. Hence, the semiconductor design and operation can be considered to improve the pre-charging process of the BLs.

The systems and methods of the technical solution provide various embodiments of a memory device for pre-charging the far end of BLs (and FBLs). The systems and methods can provide at least one pre-charging circuit (e.g., sometimes referred to as a (far end) pre-charge circuit) for pre-charging the BLs at the far end to increase the rate of pre-charging the BLs and prevent leakage from inactive cells. The pre-charging circuit can include an equalizer to pre-charge the BL and BLB, providing relatively equal pre-charge (e.g., voltage) for the BL and BLB (e.g., no pre-charge difference between the BL and BLB at the far end), thereby preventing potential read functionality issues. The pre-charging circuit can be applied or utilized for various non-limiting technology nodes. In various aspects, as supported by the technological constraints for the number of bitcells per BL, enhancements in memory density can be achieved by using the pre-charging circuit of the technical solution discussed herein, thereby minimizing or avoiding impact on the BL pre-charge times. Techniques disclosed herein can be applied in different memory technologies, including SRAM, RRAM, MRAM, phase-change memory, NVM, NOR, NAND, e-fuse, OTP, BEOL memory, etc.

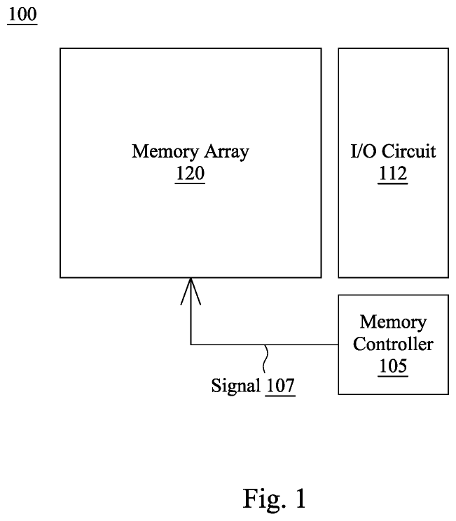

FIG. 1 illustrates a block diagram of a memory device 100 (or memory circuit), in accordance with various embodiments. The memory device 100 includes a memory array 120, a memory controller 105, and an input/output (I/O) circuit 112. Despite not being explicitly shown in FIG. 1, the memory device 100 may include other components (e.g., a bit line controller, a word line controller, etc.). Despite not being explicitly shown in FIG. 1, the components of the memory device 100 may be operatively coupled to each other and to the memory controller 105. For example, a heater may be included and thermally coupled at least to the memory array 120, while the memory controller 105, the I/O circuit 112, etc. may be electrically coupled to the memory array 120, in some embodiments. Although, in the illustrated example of FIG. 1, the component are shown as separate blocks for the purpose of clear illustration, in some other embodiments, some or all of the components shown in FIG. 1 may be integrated together. For example, the memory array 120 may include the I/O circuit 112 embedded therein.

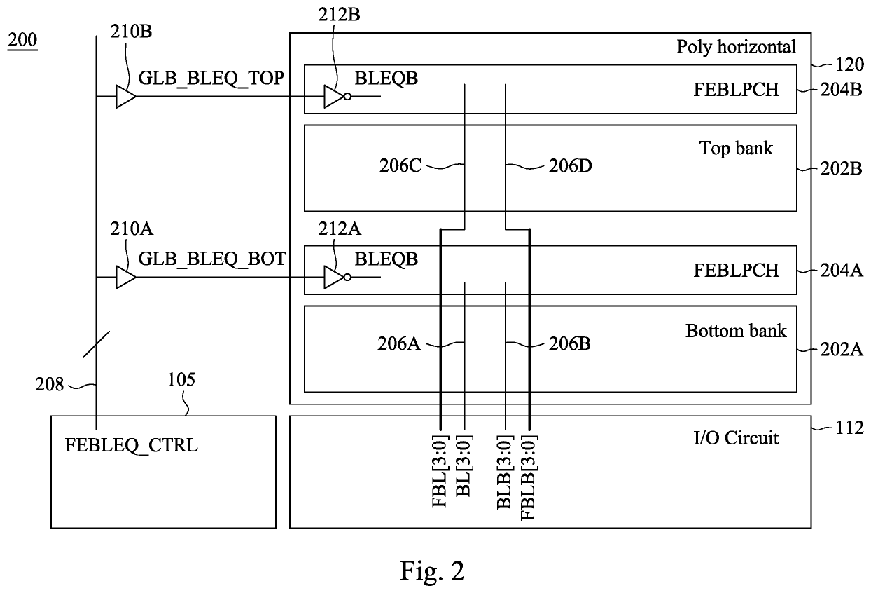

The memory array 120 is embodied as a semiconductor memory device. The memory array 120 includes a plurality of storage circuits or memory cells. The memory array 120 includes word lines WL0, WL1 . . . WLJ (not shown), each extending in a vertical direction (e.g., Y-direction) and bit lines BL0, BL1 . . . BLK (not shown), each extending in a horizontal direction (e.g., X-direction). The word lines WL and the bit lines BL may be conductive metals or conductive rails. In one configuration, each memory cell is coupled to a corresponding word line WL and a corresponding bit line BL, and can be operated according to voltages or currents through the corresponding word line WL and the corresponding bit line BL. In some embodiments, each bit line includes bit lines BL, coupled to one or more memory cells of a group of memory cells disposed along the horizontal direction (e.g., X-direction). The bit lines BL may receive and/or provide differential signals. Each memory cell may include a volatile memory, a non-volatile memory, or a combination of them. In some embodiments, each memory cell is embodied as a static random access memory (SRAM) cell or other types of memory cell. In some arrangements, the WLs and/or the BLs can be extended in other directions, such as BLs extending in the vertical direction (e.g., Y-direction), as shown in conjunction with at least FIG. 2, and the WLs extending in the horizontal direction (e.g. X-direction).

The I/O circuit 112 is a hardware component that can access (e.g., read, program) each of the memory cells in the memory array 120 asserted through at least one decoder, such as a WL decoder or a BL decoder (not shown). The I/O circuit 112 may be referred to as a main I/O (MIO). For example, a plural number of switch/selection transistors can form the I/O circuit 112. In some embodiments, the memory array 120 may be formed in a first region of a substrate, while the I/O circuit 112 may be formed in a second region of the substrate. The second region can be configured as a close-end or an open-end ring surrounding the first region. Although the second region is shown to be horizontally adjacent to the first region (e.g., disposed along a second lateral direction to one another), the second region may be vertically adjacent to the first region in some arrangements (e.g., disposed along a first lateral direction to one another), such as shown in conjunction with but not limited to FIG. 2. The regions of the substrates including the memory array 120 and the I/O circuit 112 can be disposed along other directions with respect to each other, where the I/O circuit 112 can be operatively coupled to the memory array 120 via at least one access line or connector, such as but not limited to BL, BLB, FBL, etc., as shown in conjunction with but not limited to FIG. 2.

The memory controller 105 is a hardware component that controls operations of the memory array 120. As shown in FIG. 1, the memory controller 105 can be physically located next to the I/O circuit 112. In some arrangements, the memory controller 105 may be physically located in other regions or portions of the memory device 100, such as adjacent to the memory array 120, etc. The memory controller 105 includes and/or controls the I/O circuit 112, one or more components of the memory array 120 (e.g., pre-charging circuits for pre-charging at least one BL, as described in conjunction with at least FIGS. 2-8), etc. In some examples, the I/O circuit 112, the pre-charging circuit, etc. may be embodied as logic circuits, analog circuits, or a combination of them. The memory controller 105 can provide (e.g., decoder) signals 107 to different memory cells, such as through different pairs of the first set and the second set of metal tracks. In one configuration, the memory controller 105 can control a voltage provision circuit included therein to provide a voltage signal to the I/O circuit 112, the pre-charging circuit, etc. In some embodiments, such a voltage provision circuit is embodied as or includes a processor and a non-transitory computer readable medium storing instructions when executed by the processor cause the processor to execute one or more functions of the memory controller 105 described herein. In some cases, the memory controller 105 can send the signal 107 to at least one component of the memory array 120, such as at least one pre-charging circuit. For instance, the memory controller 105 can send the signal 107 to initiate pre-charging at least one of the BLs. In another example, the memory controller 105 can send the signal 107 to terminal the pre-charging of the BLs. In some embodiments, the memory controller 105 includes more, fewer, or different components than shown in FIG. 1.

FIG. 2 illustrates a block diagram 200 of the memory device 100 of FIG. 1 including far-end bit line pre-charge circuits 204A-B (e.g., sometimes referred to as pre-charge circuit(s) 204), in accordance with various embodiments. As shown, at least a portion of the memory device 100 is provided in the block diagram 200, including at least the memory controller 105, the I/O circuit 112, the memory array 120, etc.

The memory array 120 can include multiple portions, such as a first portion and a second portion. The first portion can include or be associated with a first memory bank 202A (e.g., bottom bank). The second portion can include or be associated with a second memory bank 202B (e.g., top bank). The memory banks 202A-B may be referred to as memory bank(s) 202. In some arrangements, the memory array 120 may include a single portion with the memory banks 202 or more portions with additional memory banks 202, for example. Although the first memory bank 202A and the second memory bank 202B are presented as the bottom bank and the top bank, in some cases, the memory banks can be configured in different arrangements, such as the first memory bank 202A being the top bank and the second memory bank 202B being the bottom bank, for example.

The memory banks 202 can be positioned or physically disposed along a first lateral direction (e.g., vertical or Y-direction in this case). For purposes of providing examples herein, the I/O circuit 112 can be disposed next to the memory array 120 along the first lateral direction, where the first memory bank 202A is closer to the I/O circuit 112, interposed between the second memory bank 202B and the I/O circuit 112.

The memory array 120 can include one or more pre-charge circuits 204. The pre-charge circuit 204 may be referred to as far end BL pre-charge circuit (FEBLPCH). For example, the memory array 120 can include a first pre-charge circuit 204A and a second pre-charge circuit 204B. There may be more or less pre-charge circuits 204 according to the configurations of the memory device 100. In some cases, the number of pre-charge circuits 204 can correspond to the number of memory banks 202 (or sets of BLs coupled to the respective memory banks 202). The pre-charge circuit 204 can be disposed next/adjacent to the respective memory bank 202 along the first lateral direction. The pre-charge circuit 204 can be physically disposed opposite the portion, including the respective memory bank 202, from the I/O circuit 112. For example, the first pre-charge circuit 204A can be disposed next to the first memory bank 202A along the first lateral direction, opposite from the I/O circuit 112. The second pre-charge circuit 204B can be disposed next to the second memory bank 202B along the first lateral direction opposite, opposite from the first pre-charge circuit 204A and/or the first memory bank 202A.

The memory device 100 can include one or more access lines 206A-D (e.g., sometimes referred to as access lines 206). The access lines 206 may extend in the first lateral direction. The access lines 206 can include or correspond to BLs or FBLs. In some cases, each access line 206 can include a complementary access line 206. For instance, a BL can be paired with a complementary BL (e.g., BLB). A FBL can be paired with a complementary FBL (e.g., FBLB). Each access line 206 can be coupled to the I/O circuit 112, the respective memory bank 202, and the respective pre-charge circuit 204. In some implementations, the BL can be referred to as a first access line. The FBL can be referred to as a second access line. The BLB can be referred to as a third access line. The FBLB can be referred to as a fourth access line. In some other implementations, any of the BLs (e.g., BL, BLB, FBL, or FBLB) may be referred to as first, second, third, etc., access lines, for example.

For example, BL and BLB can be coupled to the I/O circuit 112, the first memory bank 202A, and the first pre-charge circuit 204A. The FBL and FBLB can be coupled to the I/O circuit 112, the second memory bank 202B, and the second pre-charge circuit 204B. The FBL can refer to or represent a BL flying over at least a portion of the memory array 120. In this case, the FBL (and FBLB) can fly over the first memory bank 202A and the first pre-charge circuit 204A to couple with the second memory bank 202B and the second pre-charge circuit 204B. Since the FBL and the FBLB fly over the first memory bank 202A and the first pre-charge circuit 204A, the FBL and the FBLB are not coupled to the first memory bank 202A and the first pre-charge circuit 204A.

For example, the FBL (or the FBLB) can include multiple segments disposed in different metallization. The BL and BLB may extend from the I/O circuit 112 to the first pre-charge circuit 204A and disposed in a first metallization layer to operatively couple to the memory cells of the first memory bank 202A and/or one or more components of the first pre-charge circuit 204A. The FBL and FBLB can include a first segment and a second segment that extend from the I/O circuit 112 to the second pre-charge circuit 204B, for instance. The first segment can be disposed in a second metallization layer that is above the first metallization layer. The first segment can extend from the I/O circuit 112 across the first memory bank 202A and the first pre-charge circuit 204A, such that the first segment of the FBL and the FBLB does not couple to the memory cells of the first memory bank 202A and the components of the first pre-charge circuit 204A. The second segment can extend from the first segment to the second pre-charge circuit 204B, where the second segment of the FBL and FBLB can be operatively coupled to at least one of the memory cells of the second bank 202B and/or the one or more components of the second pre-charge circuit 204B. The memory device 100 can include additional FBLs flying over portions of the memory array 120.

The memory controller 105 may write data to or read data from the memory bank 202 according to electrical signals through the access lines 206. For example, the access lines 206 can be coupled to the respective memory banks 202. Each memory cell of the memory banks 202 can be coupled to a respective access line 206 (e.g., BL or in some cases WL). The access lines 206 can carry, receive, or transmit signals between the I/O circuit 112 and the one or more memory cells of the memory bank 202. In some cases, the access lines 206 may include WLs. Each memory cell can be operated according to voltages or currents through the corresponding bit line BL (or the corresponding word line WL).

The read and write operations can be performed via the access lines 206 (e.g., the BL or FBL). In certain scenarios, to write data to a memory cell, the I/O circuit 112 can apply a voltage or current corresponding to data to be stored in the memory cell through the access line 206 (e.g., BL) coupled to the memory cell. In this case, the access line 206 can function as a conduit for the transmission of data, allowing for write interactions with the memory array.

In another scenario, to read data from the memory cell, at least one selected access line 206 can be utilized to retrieve data from the memory cells. For example, via a sensing mechanism, the state of individual memory cells can be detected along the addressed access line 206. In this case, the I/O circuit 112 (or other components of the memory device 100) can be configured to sense a voltage or current corresponding to data stored by the memory cell through the access line 206 (e.g., a corresponding BL) coupled to the memory cell, thereby allowing the retrieval of stored information from the memory cell (e.g., for subsequent processing). The read or write operation can be initiated by the memory controller 105. For instance, the memory controller 105 may send a signal (e.g., signal 107) to the memory array 120 for the memory cells to output corresponding voltages for detection by the I/O circuit 112. The memory controller 105 may send a signal to the I/O circuit 112 indicating the voltage or current corresponding to the data, such that the I/O circuit 112 can apply the voltage or current for writing the data to at least one (e.g., selected) memory cell.

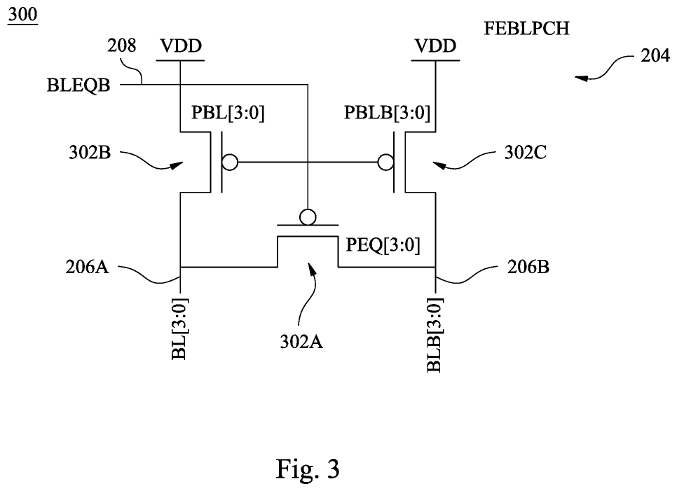

Each access line 206 can be coupled to the respective pre-charge circuit 204. The pre-charge circuit 204 can be at the distal end (e.g., far end) of the access line 206, opposite the proximal end of the access line 206 which is coupled to the I/O circuit 112. The pre-charge circuit 204 can be configured to set voltages at one or more access lines 206 to a predetermined voltage level. The pre-charge circuit 204 can be used to minimize the time to achieve pre-charging onto the BLs at the far end (or improve pre-charging efficiency at the far end of the BLs), thereby preventing potential functional issues during, for instance, read operation caused by a difference in pre-charge level between the BL and the BLB (or FBL and FBLB). The operations or features of the pre-charge circuit 204 can be described in conjunction with at least one of but not limited to FIGS. 3-8. For example, the pre-charge circuit 204 is a circuit or a component that can set or pre-charge voltages at one or more BLs (or FBLs). In some embodiments, the pre-charge circuit 204 is implemented as one or more switches or one or more transistors, such as described in conjunction with but not limited to FIGS. 3-8. In some embodiments, the pre-charge circuit 204 can be replaced by a different component that can perform the functions of the pre-charge circuit 204 described herein.

In various configurations, the pre-charge circuit 204 can be controlled, according to a pre-charge control signal (e.g., signal 107), or other signals from the memory controller 105 or other components of the memory device 100. For example, the pre-charge circuit 204 may be activated/enabled to set or pre-charge voltages at the BLs to a predetermined voltage level (e.g., VDD or 1V), in response to the signal 107 from the memory controller 105 having a first voltage (e.g., VDD or 1V). In another example, the pre-charge circuit 204 may be disabled/deactivated, such that the pre-charge circuit 204 may not set or pre-charge voltages at the BLs in response to the signal 107 from the memory controller 105 having a second voltage (e.g., VSS or 0V).

In some configurations, the memory controller 105 may send a high signal (e.g., 1V) to the pre-charge circuit 204 to activate or start pre-charging the BLs coupled to the pre-charge circuit 204. In some other configurations, the memory controller 105 may send a low signal (or stop sending signals) for the pre-charge circuit 204 to start pre-charging the BLs. In this case, the signal from the memory controller 105 can be inverted for the pre-charge circuit 204.

For example, as shown in FIG. 2, the memory controller 105 can be coupled to the pre-charge circuits 204 via at least one control line 208. The control line 208 can include first segments extending along the first lateral direction, and second segments extending along a second lateral direction (e.g., horizontal direction in this case), where the second segments are coupled to the pre-charge circuit 204 for activating or deactivating the functionality of the pre-charge circuit 204. The control line 208 can include one or more buffers 210A-B (e.g., sometimes referred to as buffer(s) 210) or one or more inverters 212A-B (e.g., sometimes referred to as inverter(s) 212). The memory controller 105 can send the signal 107 through the buffer 210 and the inverter 212 for controlling the pre-charge circuit 204.

The buffer 210 may be used for signal conditioning (e.g., conditioning the signal 107), amplification, isolation, timing control, etc. The buffer 210 can be used to improve or maintain the quality or integrity of the signal 107 from the memory controller 105 to the pre-charge circuit 204, for example. In this case, the buffer 210 may be a signal integrity buffer. In some cases, the control line 208 may not include the buffer 210. The inverter 212 can be used to invert the signal from the memory controller 105, such that a high signal (e.g., 1V) received from the memory controller 105 can be inverted to a low signal (e.g., 0V), or vice versa. For purposes of providing examples herein, the control line 208 can include the inverters 212, such that when sending the low signal (e.g., no signal or second voltage), the one or more switches or transistors of the pre-charge circuit 204 can be activated, thereby initiating the pre-charging of the BLs. In some implementations, the inverter 212 may not be included in the control line 208, such that the memory controller 105 can initiate the operation of the pre-charge circuit 204 by sending the high signal (e.g., 1V or the first voltage).

In some configurations, the read and/or write operation may be performed through multiple phases when using the pre-charge circuit 204, such as a pre-charging phase and a read or write phase. For example, in the pre-charging phase, the memory controller 105 can generate the signal 107 (e.g., the pre-charge control signal) having the second voltage (e.g., 0V) to activate the pre-charge circuit 204. In some cases, generating the signal 107 having the second voltage may refer to not sending the signal 107 (or preventing the memory controller 105 from sending the signal 107) to the pre-charge circuit 204. Via the inverter 212, the second voltage can be inverted, such that a predetermined voltage is applied to the transistors or switches of the pre-charge circuit 204, thereby initiating the pre-charging operation. For instance, the inverter 212 may be connected to a power line, e.g., VDD or power source. Upon applying the second voltage at the input of the inverter 212, the inverter 212 can output the VDD (e.g., 1V), thereby activating the pre-charge circuit 204 to pre-charge the BL and BLB, for example. Activating the pre-charge circuit 204 can activate an equalizer (e.g., transistor 302) of the pre-charge circuit 204, such as described in conjunction with at least one of but not limited to FIGS. 3-8. The equalizer can be used to equalize the voltages of the BL and the BLB, or at least a (far end) portion of the BL and BLB. The pre-charging phase can transition to the read or write phase when the I/O circuit 112 is ready to perform the read or write operation.

In the read or write phase, the memory controller 105 can generate the signal 107 having the first voltage (e.g., 1V). Via the inverter 212, the first voltage can be inverted, such that there is no voltage applied to the transistors or switches of the pre-charge circuit 204 (or a voltage below a voltage threshold is applied), thereby deactivating the pre-charging operation. Deactivating the pre-charge circuit 204 can include deactivating the equalizer. The read or write operation can be performed while or in response to deactivating the pre-charge circuit 204.

For example, to perform the read operation (e.g., read phase), if the memory cell stores a value ‘1’, the voltage at the BLB (e.g., the complementary BL) may decrease and may become lower than the voltage at the BL. If the memory cell stores a value ‘0’, the voltage at the BL may decrease and may become lower than the voltage at the BLB. The I/O circuit 112 or other components of the memory device 100 can sense voltages at the BL and/or the BLB in the read phase, and determine data stored by the memory cell, according to the sensed voltages.

In another example, to perform the write operation (e.g., write phase), the I/O circuit 112 can apply data signals corresponding to data to write to the BL and/or the BLB. In some cases, the I/O circuit 112 can receive the signal 107 from the memory controller 105 indicating the data to write to the BL and/or the BLB, such that the I/O circuit 112 can apply the data signals. Additionally or alternatively, other components of the memory device 100 may send signals to the I/O circuit 112 to apply the data signals for writing data to at least one corresponding memory cell. In response to performing the read or write operation, the memory controller 105 can send the signal 107 to (re-)activate the pre-charge circuit 204.

Similar operations can be performed for pre-charging at least a portion of the FBL and FBLB. For example, at least a portion of the FBL and the FBLB can be pre-charged by the pre-charge circuit 204 (e.g., the second pre-charge circuit 204B) in response to receiving the signal 107 (or voltage) from the memory controller 105. The portion pre-charged by the pre-charge circuit 204 can include at least the far end or distal portion of the FBL and FBLB opposite from the I/O circuit 112. The FBL and FBLB can be pre-charged while no data is being read from or written to the memory cell. The pre-charge circuit 204 can deactivate the pre-charging process for the FBL and the FBLB during the read or write operation for the memory cells of the memory bank 202 (e.g., the second memory bank 202B).

In some arrangements, the pre-charge circuits 204 for the BL, BLB, FBL, and FBLB can be activated and deactivated synchronously. In some other arrangements, the pre-charge circuits 204 for the BL, BLB, FBL, and FBLB can be activated and deactivated independently, such that the first memory bank 202A may be activated when the second memory bank 202B is deactivated, or vice versa.

In some configurations, the memory device 100 may include a near-end pre-charge circuit at the proximal end of the BLs. The near-end pre-charge circuit is different from the pre-charge circuits 204. For example, the near-end pre-charge circuit may be a part of the I/O circuit 112. In another example, the near-end pre-charge circuit may be disposed along the first lateral direction interposing the I/O circuit 112 and the memory array 120 (or the memory banks 202). The near-end pre-charge circuit can be operated by the memory controller 105 for pre-charging the near-end of the BLs. The near-end of the BLs may refer to a portion of the BL that is adjacent or proximal to the I/O circuit 112.

In some implementations, the memory device 100 may include multiple near-end pre-charge circuits. For example, similar to the pre-charge circuits 204, the memory array 120 may include a respective near-end pre-charge circuit for each memory bank 202. In such cases, a first near-end pre-charge circuit can be physically disposed in the first lateral direction opposite the first memory bank 202A from the first pre-charge circuit 204A. A second near-end pre-charge circuit can be physically disposed in the first lateral direction opposite the second memory bank 202B from the second pre-charge circuit 204B. Each near-end pre-charge circuit, among other pre-charge circuits, may be coupled to the memory controller 105 via the control line 208 extending in the second lateral direction, for example. The BL and BLB may be operatively coupled to the first near-end pre-charge circuit. The FBL and the FBLB may be operatively coupled to the second near-end pre-charge circuit. In some other cases, the memory device 100 may not include the near-end pre-charge circuit.

FIG. 3 illustrates a schematic diagram 300 of a first example far-end bit line pre-charge circuit (e.g., the pre-charge circuit 204A) of FIG. 2, in accordance with various embodiments. Although the examples herein illustrate an example schematic of the pre-charge circuit 204A, e.g., for pre-charging the BL and BLB, the operations or features discussed herein can be applied to other pre-charge circuits 204, such as the pre-charge circuit 204B for pre-charging the FBL and FBLB. As shown, the schematic diagram 300 shows the pre-charge circuit 204 including a plurality of transistors 302A-C. The transistors 302A-C can sometimes be referred to as transistor(s) 302 or switch(es) 302. The transistors 302 may operate as switches. As shown, the control line 208 can be operatively coupled to the gates (e.g., gate electrodes) of the transistors 302 for controlling or operating the transistors 302.

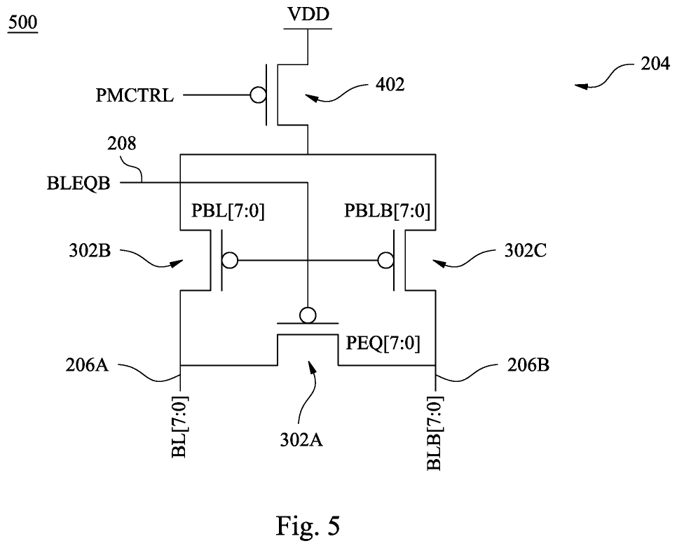

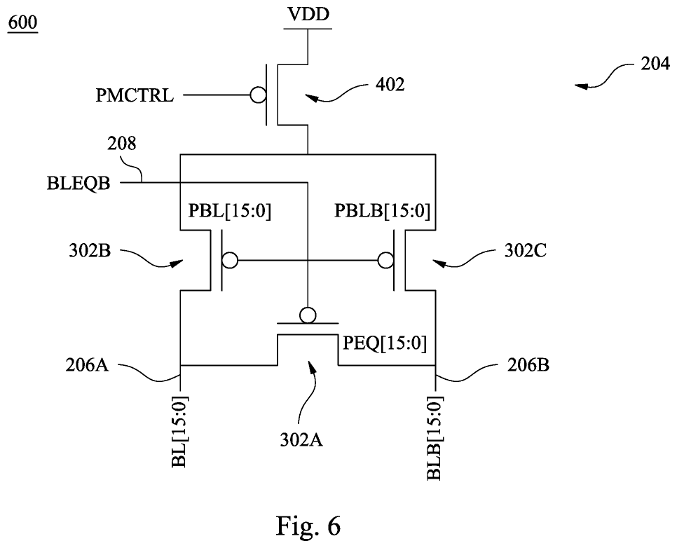

While not shown in at least FIGS. 3-8, the control line 208 can include at least the inverter 212 to convert or invert the signal 107 from the memory controller 105 to the pre-charge circuit 204. In this case, the inverter 212 can convert the signal 107 or voltage from the memory controller 105 to the gates of the transistors 302. The schematic diagram 300 shows an example of the pre-charge circuit 204 for a 4-to-1 multiplexer (MUX4), although the pre-charge circuit 204 can be utilized for other types of MUX not limited to MUX4, as described in conjunction with at least FIGS. 5-6, for example. The pre-charge circuit 204 can be utilized at the far end of the BLs to increase the efficiency of pre-charging the BLs, where the BL pre-charge time may be relatively long depending on the BL resistance (e.g., large or lengthy metal structure), and prevent leakage from inactive memory cells. In some cases, the structures, components, or layout of the pre-charge circuit 204 may be similar to other pre-charge circuits, such as other far end pre-charge circuits 204 or near-end pre-charge circuits, for example.

The signal 107 from the memory controller 105, after the inverting by the inverter 212, can be represented by the BL equalizer B (BLEQB) signal. The BLEQB signal can be used to control the transistors 302 for activating or deactivating the pre-charge circuit 204. The transistors 302 in this disclosure are shown to have a certain type (e.g., P-type or P-channel MOSFET (PMOS) in this case), but embodiments are not limited thereto and the transistors 302 may be of other types, such as N-type, among others.

Before the read or write operation, the memory controller 105 can maintain the BL and BLB in a predefined state (e.g., high or pre-charged state, depending on the configuration). To initiate the pre-charging, the memory controller 105 can send a high signal, such that the BLEQB signal (or the inverted signal) is low. The low BLEQB signal can correspond to the first voltage (e.g., 1V or VDD) applied to the gate electrodes of the transistors 302. When the first voltage is applied to the gate electrodes, across the source electrode and the drain electrode of the transistors 302, the transistors 302 can allow current to flow from the source to the drain. Allowing the current to flow via the transistor 302 may correspond to turning on a switch or activating the transistor 302. For example, in response to applying the first voltage at the transistors 302B, 302C, the pre-charge circuit 204 can start pre-charging the corresponding BL and BLB. The pre-charge circuit 204 can set the BL and BLB to the predetermined voltage level (e.g., VDD) when the transistors 302B, 302C are activated. The transistor 302B can be denoted as PBL (e.g., PMOS transistor associated with the BL). The transistor 302C can be denoted as PBLB (e.g., PMOS transistor associated with the BLB).

The pre-charge circuit 204 can include an equalizer, corresponding to the transistor 302A (e.g., denoted as PEQ, such as PMOS transistor configured as an equalizer). The transistor 302A (e.g., the equalizer) can be configured to equalize the voltage between the BL and the BLB. In some cases, the equalizer may be a circuit or other components configured to selectively couple the BL and BLB. For purposes of providing examples herein, the equalizer is implemented as the transistor 302A, although the equalizer may be implemented as one or more switches or one or more transistors. In some embodiments, the equalizer can be replaced by a different component that can perform the functions of the equalizer described herein. In one configuration, the equalizer is coupled to the BL and BLB. In some embodiments, the equalizer can be controlled, according to BLEQB signal, similarly to the transistors 302B, 302C.

For example, the equalizer may be activated/enabled to electrically couple the BL to the BLB, in response to the first voltage (e.g., VDD or 1V) applied at the gate electrode of the transistor 302A via the BLEQB signal. In another example, the equalizer may be disabled to electrically decouple the BL from the BLB, in response to receiving the second voltage (e.g., VSS or 0V) or having the second voltage applied to the gate electrode of the transistor 302A (or lack of voltage thereof). In such cases, by coupling the BL and BLB, the voltages between the BL and BLB can be equalized to prevent, for instance, potentially functional errors during read or write operation of the memory device 100.

To perform the read or write operation, the pre-charge circuit 204 can be deactivated. Deactivating the pre-charge circuit 204 can include deactivating the transistors 302 to prevent the pre-charging of the BL and BLB, e.g., at the far end of the BLs. For example, the BLEQB signal can include the second voltage (e.g., VSS or 0V) applied to the gate electrodes of the transistors 302. The second voltage applied to the gate electrode of the transistor 302A can decouple the BL and BLB. The second voltage applied to the gate electrodes of the transistors 302B, 302C can disable current flow between the source and drain. Accordingly, the pre-charge circuit 204 can terminate pre-charging the BL and BLB, so that the read or write operation can be properly performed via the BL and BLB, including but not limited to carrying signals from the memory cells to the I/O circuit 112 or carrying the data signals to store in the memory cells.

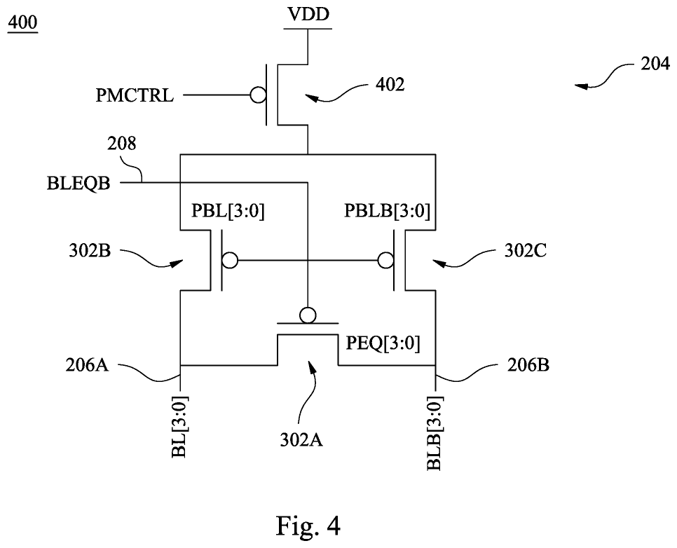

FIG. 4 illustrates a schematic diagram 400 of a second example far-end bit line pre-charge circuit (e.g., pre-charge circuit 204) of FIG. 2, in accordance with various embodiments, the pre-charge circuit 204 of FIG. 4 can include one or more similar components as those shown in FIG. 3, including but not limited to the transistors 302, the BLEQB signal inverted from the signal 107 of the memory controller 105, the BLs, or the power line or source (e.g., VDD) used to pre-charge the BL and BLB. In this case, the pre-charge circuit 204 can include a power-gating feature by adding a header in the pre-charge circuit 204. The header may include one or more transistors or one or more switches. For purposes of providing examples, the header can include transistor 402, providing the power-gating feature.

The transistor 402 can be controlled or operated by a control signal, e.g., power management control (PMCTRL) signal. The PMCTRL signal can be sent by the memory controller 105. The PMCTRL signal can be different from the BLEQB signal. The power-gating feature can be used for reducing power consumption, improving energy efficiency, or selective power control, among others. For instance, until the transistor 402 is activated, the BL and BLB may not pre-charge even with the transistors 302 being activated or turned on. The pre-charge circuit 204 can initiate the pre-charging process when the first voltage (or high voltage) is applied to the transistors 302, 402 to form a conductive channel between the source and drain terminals and allow current to flow from the power line or power source (e.g., VDD) to the BL and BLB. In some cases, the power source may be an internal power source coupled to the memory device 100 or one or more components of the memory device 100, such as a battery.

In some implementations, the power-gating feature can be used to selectively activate or deactivate different pre-charge circuits 204. For example, the memory controller 105 can send a first PMCTRL signal to the first pre-charge circuit 204A and a second PMCTRL signal to the second pre-charge circuit 204B. As an initial setting (e.g., the predefined state), the memory controller 105 can set the first and second PMCTRL signals to the first voltage to activate the transistor 402. The BLEQB signal can be set to the first voltage as part of the predefined state. In this case, the first and second pre-charge circuits 204A, 204B can start pre-charging the respective BLs, for instance, the first pre-charge circuit 204A can pre-charge the BL and BLB, and the second pre-charge circuit 204B can pre-charge the FBL and FBLB. In some cases, the read or write operation may be performed on one of the memory banks 202, such as the first memory bank 202A. In this case, the second PMCTRL signal and the BLEQB signal can remain at the first voltage, such that the FBL and FBLB can remain in the pre-charged state. The memory controller 105 can apply the first PMCTRL signal with the second voltage (e.g., 0V) to the transistor 402 to turn off the conductive channel between the source and drain terminals of the transistor 402. Turning off the transistor 402 can disable current flow between the source and drain of the transistor 402, thereby preventing pre-charging of the BL and BLB. In response to turning off the transistor 402, the memory controller 105 and the I/O circuit 112 can perform the read or write operation on the memory cells of the first memory bank 202A, and the FBL and FBLB can remain in the pre-charge state. Accordingly, with the power-gating feature implemented using the transistor 402, the memory device 100 can allow for selective pre-charging of one or more BLs (or one or more sets of BLs).

It should be noted that FIG. 4 provides MUX4 as an example, and other types of MUX or devices configured to perform similar features can be utilized herein for the pre-charge circuit 204. For example, FIG. 5 illustrates a schematic diagram 500 of a third example far-end bit line pre-charge circuit (e.g., pre-charge circuit 204) of FIG. 2, in accordance with various embodiments. The pre-charge circuit 204 of FIG. 5 includes one or more similar components as the pre-charge circuit 204 of FIG. 4, for example. As shown, an 8-to-1 MUX (MUX8) can be implemented as part of the pre-charge circuit 204. In another example, FIG. 6 illustrates a schematic diagram 600 of a fourth example far-end bit line pre-charge circuit (e.g., pre-charge circuit 204) of FIG. 2, in accordance with various embodiments. The pre-charge circuit 204 of FIG. 6 includes one or more similar components as the pre-charge circuit 204 of at least one of FIGS. 4-5, for example. As shown, a 16-to-1 MUX (MUX16) can be implemented as part of the pre-charge circuit 204. In various arrangements, other components or devices may be implemented as part of the pre-charge circuit 204 or the memory device 100 to pre-charge the far end of the BLs.

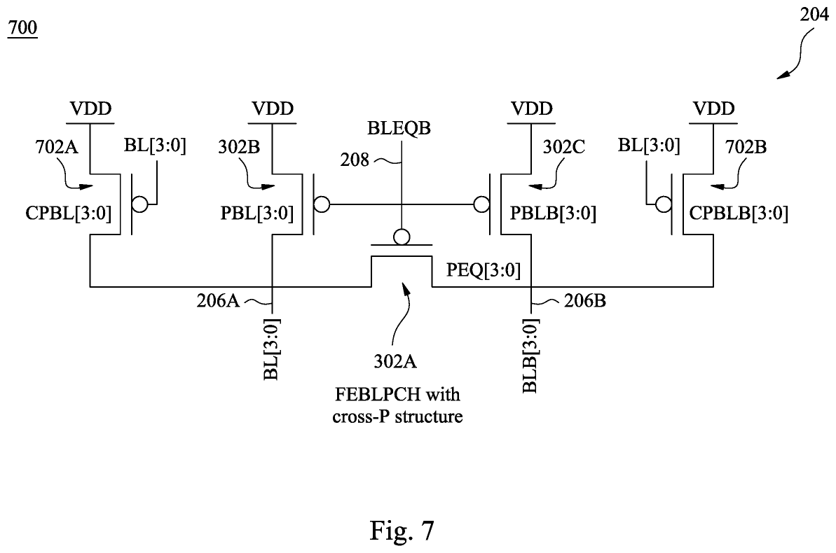

FIG. 7 illustrates a schematic diagram 700 of a fifth example far-end bit line pre-charge circuit (e.g., pre-charge circuit 204) of FIG. 2, in accordance with various embodiments. The pre-charge circuit 204 of FIG. 7 can include one or more similar components as the pre-charge circuit 204 of at least one of FIGS. 2-6, for example. As shown, the pre-charge circuit 204 can include the control line 208 operatively coupled to the gate electrodes of the transistors 302 to apply the BLEQB signal. In this case, a cross-P structure can be implemented for the pre-charge circuit 204.

For example, transistors 702A-B (e.g., sometimes referred to as transistor(s) 702) can be implemented as part of the cross-P structure. The transistor 702A can be denoted as CPBL (e.g., a transistor for the BL of the cross-P structure). The transistor 702B can be denoted as CPBLB (e.g., a transistor for the BLB of the cross-P structure). The transistors 702 can be a P-type transistor, although other types of transistors can be utilized herein, such as N-type transistors. The gate electrode of the transistor 702A can be operatively coupled to the BLB. The gate electrode of the transistor 702B can be operatively coupled to the BL. In this case, the cross-P structure can be utilized to counter potential leakage from the remaining bitcells (e.g., bitcells not being actively accessed) in the same column of the memory array 120 or the memory bank 102, such as when the bitcells have ‘0’ stored on the respective side of the memory array 120.

For example, before the active operation (e.g., read or write operation), the BLEQB signal can be at the first voltage, such that the BL and BLB can be in the high voltage state. During the active operation, e.g., when the value in at least one memory cell is being sensed in the read operation, any unintended leakage may impact the accuracy of the readout via the BL or the BLB, such as in cases where the stored value is ‘0’. To counter the potential leakage, the BL or the BLB can be held high (e.g., holding the BL and/or BLB at the first voltage or the pre-charged voltage) using the transistors 702. Holding the BL or the BLB at the pre-charged voltage can counter the leakage because the pre-charged voltage compensates for the potential loss of charge from the memory cells, thus reducing the likelihood of misreading during the data sensing process. In this case, during the read operation (or the write operation), the transistors 302 can be deactivated to stop pre-charging the BL and BLB, and the BL and BLB may be floating. In some cases, unselected rows of memory cells may cause the BL or the BLB to discharge causing a differential between the voltages at the BL and BLB. For instance, if the BLB is discharging voltage and the BL is at the high voltage, the transistor 702B can be activated allowing current to flow to the BLB, thereby ensuring that the BLB is maintained at the high voltage (e.g., first voltage). Likewise, when there is a leakage from the BL and the BLB is at the high voltage, the transistor 702A can be activated allowing current to flow to the BL, thereby ensuring the BL is maintained at the high voltage. By ensuring that the BL or the BLB is maintained at the high voltage, the leakage from the BL or the BLB can be countered.

In further examples, to counter the potential leakage and while reading the value ‘1’ from at least one bitcell, the BL can be maintained in the high voltage state, and the BLB may begin/start to discharge. In this example, the CPBLB (e.g., transistor 702B) can be turned off because the BL is in the high voltage state. The CPBL (e.g., transistor 702A) can be turned on when the BLB starts discharging. In such cases, the CPBL can assist with holding or maintaining the BL in the high state to counter the (potential) leakage from other bitcells on the same column, e.g., which may be storing the value ‘0’.

Similar operations or features can be applied to other pre-charge circuits 204 and BLs, such as for the second pre-charge circuit 204B and the corresponding FBL and FBLB. The pre-charge circuit 204 of FIG. 7 provide the cross-P structure implemented for MUX4, as an example. Other types of MUX or devices can be implemented not limited to MUX4, such as MUX8, MUX16, etc.

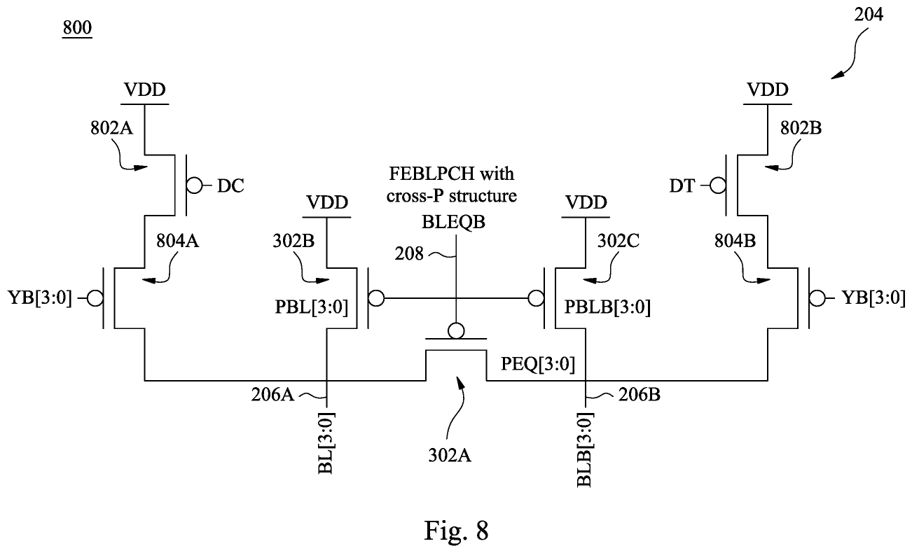

FIG. 8 illustrates a schematic diagram 800 of a sixth example far-end bit line pre-charge circuit of FIG. 2, in accordance with various embodiments. The pre-charge circuit 204 of FIG. 8 can include one or more similar components as the pre-charge circuit 204 of at least one of FIGS. 2-7, for example. In this case, another example cross-P structure can be implemented for the pre-charge circuit 204. The cross-P structure of FIG. 8 can be utilized for the write operation, for example, by implementing one or more data buses (e.g., data bus T (DT) and data bus C (DC)) and column decoder. The data buses and the column decoder can be used to control the operation of the respective transistors, such as transistors 802A-B (e.g., sometimes referred to as transistor(s) 802) controlled by the data buses, and transistors 804A-B (e.g., sometimes referred to as transistor(s) 804) controlled by the column decoder.

The cross-P structure of FIG. 8 can hold the BL or BLB high (e.g., at the first voltage) when the WL turns on before the write drivers (not shown) (e.g., no pre-write), which in such cases, a dummy read may potentially occur. For example, during a write operation for a value of ‘0’, the data (e.g., the value ‘0’) can be placed onto or provided to the BL. In this example, DT can be 0 and DC can be 1. Because DC is 1, the transistor 802A can be off to allow the BL to discharge from the write driver, such as in the main input/output (I/O). Having the DT at 0 can assist with holding ‘1’ onto the BLB, for example. In various implementations, the cross-P structure of FIG. 8 can be used additionally or alternatively with other far end write assist circuitry that is implemented at the far end of the BL and BLB to enhance the minimum voltage (Vmin) for the write operation. The cross-P structure of FIG. 8 can be implemented for other types of MUX or devices, not limited to MUX4.

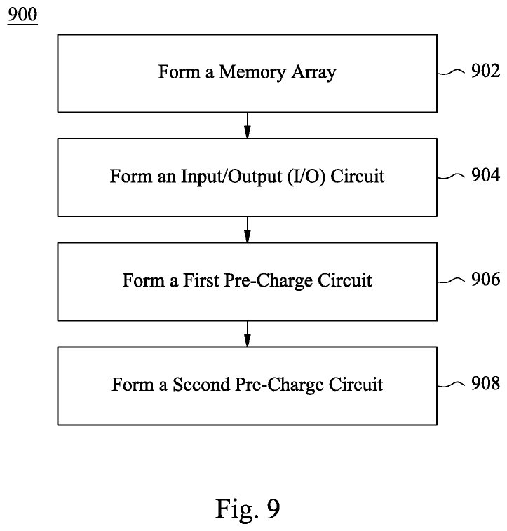

FIG. 9 illustrates a flow of an example method 900 for manufacturing a memory device (e.g., 100), in accordance with some embodiments. The method 900 can be performed to form any of memory devices herein or a portion thereof. For example, the method 900 can be performed to form any of the memory devices or a component thereof discussed with respect to FIG. 1 to FIG. 8. For example, at least one of operations of the method 900 may be performed to form a memory device (e.g., 100). Accordingly, the following discussion of the method 900 may refer to some of the reference numerals used in FIG. 1 to FIG. 8 as a non-limiting example. Further, the method 900 is merely an example, and is not intended to limit the present disclosure. It should thus be understood that additional operations may be provided before, during, and after the method 900 of FIG. 9, and that some other operations may only be briefly described herein. The method 900 can be performed simultaneously and/or in any order other than the order depicted in FIG. 9.

The method 900 can start with operation 902 of forming a memory array (e.g., 120) in an area of a substrate. The substrate may be a wafer, such as a silicon wafer, or a silicon-on-insulator (SOI) substrate. In some cases, an SOI substrate can include a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

The memory array includes a plurality of memory cells. In some examples, each of the memory cells may be implemented as a six-transistor (6T) static random access memory (SRAM) cell that consists of six transistors (e.g., N1, N2, N3, N4, P1, and P2). However, it should be understood that the first to fourth memory cells may be implemented as other type of SRAM configurations than 6T, e.g., eight transistor (8T) or ten transistor (10T) configurations. In some examples, alternatively or additionally, the memory cells may be implemented as other type of memory cells such as, for example, dynamic random access memory (DRAM) cells, resistive random access memory (RRAM) cells, phase-change random access memory (PCRAM) cells, or magnetoresistive random access memory (MRAM) cells. In various embodiments, the memory cells may be formed along a major (e.g., frontside) surface of the substrate. According to fabrication of these memory cells (and corresponding memory arrays) may sometimes be referred to as front-end-of-line (FEOL) processing.

In some configurations, the memory array can include multiple portions of the memory cells, such as a first portion and a second portion. The first portion of the memory array can include a plurality of first memory cells. The second portion of the memory array can include a plurality of second memory cells. The first portion may correspond to a first memory bank (e.g., 202A) and the second portion may correspond to a second memory bank (e.g., 202B).

At operation 904, the method 900 can include forming an I/O circuit (e.g., 112). The I/O circuit can be physically disposed next to the memory array along a first lateral direction, e.g., vertical direction as described in conjunction with FIG. 2 or horizontal direction as described in conjunction with FIG. 1. The I/O circuit can be operatively coupled to the first portion (e.g., the first memory bank) via/through a first access line. The I/O circuit can be operatively coupled to the second portion (e.g., the second memory bank) via a second access line. In this case, the first access line can refer to a BL (e.g., 206A) and the second access line can refer to a FBL (e.g., 206C).

Each of the memory cells from the portions of the memory array may be coupled to one another through the respective access line. For example, the plurality of first memory cells can be coupled to one another through the first access line. The plurality of second memory cells can be coupled to one another through the second access line. In some arrangements, there may be other access lines coupling the I/O circuit to the respective portions of the memory array. For example, a third access line (e.g., 206B, referring to BLB) can be formed, physically extending along the first lateral direction and operatively coupled to the first portion, the I/O circuit, and the first pre-charge circuit, in addition to the first access line. A fourth access line (e.g., 206D, referring to FBLB) can be formed physically extending along the first lateral direction and operatively coupled to the second portion, the I/O circuit, and the second pre-charge circuit, in addition to the second access line. The first access line and the third access line can operate as a pair of BLs for executing the read or write operations for the plurality of first memory cells. Similarly, the second access line and the fourth access line can operate as a pair of BLs for executing the read or write operations for the plurality of second memory cells.

The I/O circuit can include one or more hardware components configured to access the one or more memory cells of the memory array via at least one of the first access line or the second access line, among other access lines. The I/O circuit can access the memory cells to perform a read operation or a write operation, such as according to the signal from a memory controller (e.g., 105). For example, the I/O circuit can send a signal corresponding to the data for writing to at least one memory cell. In another example, the I/O circuit can be configured to sense a voltage or current corresponding to data stored by the memory cell through at least one of the first or the second access lines. The I/O circuit can execute similar operations using the third and fourth access lines for accessing the memory cells of the first portion and the second portion, respectively.

At operation 906, the method 900 can include forming a first pre-charge circuit (e.g., 204A). The first pre-charge circuit can be physically disposed opposite the first portion from the I/O circuit along the first lateral direction. The first pre-charge circuit can be configured to charge the first access line (and the third access line) to a supply voltage prior to accessing the first memory cells.

At operation 908, the method 900 can include forming a second pre-charge circuit. The second pre-charge circuit can include similar components or features as the first pre-charge circuit. In some cases, the second pre-charge circuit may include different components or features from the first pre-charge circuit, such as additional or alternative components (e.g., transistors, switches, or functionalities). The second pre-charge circuit can be physically disposed opposite the second portion from the first pre-charge circuit along the first lateral direction. The second pre-charge circuit can be configured to charge at least a portion of the second access line (and the fourth access line) to the supply voltage prior to accessing the plurality of second memory cells. The portion of the second access line (and the fourth access line) can include the far end portion or segment opposite from the proximal end of the second access line coupled to the I/O circuit, for example.

In some configurations, the pre-charge circuit (e.g., the first and/or the second pre-charge circuit) can include one or more transistors (e.g., 302B, 302C) operating as a switch for charging (e.g., initiating the pre-charging of) the respective access line. For example, the first pre-charge circuit can include a transistor (e.g., 302B, sometimes referred to as a first transistor) including a first source/drain (S/D) electrode, a second S/D electrode, and a gate electrode. The first S/D electrode can be operatively coupled to the first access line. The second S/D electrode can be operatively coupled to a power source (e.g., VDD or 1V). The gate electrode can be coupled to a control line (e.g., 208) (or multiple control lines) configured to send a signal (e.g., high voltage or low voltage). By applying the high voltage at the gate electrode, the transistor can be turned on, allowing the pre-charging of the first access line to the supply voltage (e.g., predefined voltage level) according to the voltage applied at the gate electrode (e.g., gate voltage).

A similar operation can be applied to the second pre-charge circuit. For example, the second pre-charge circuit can include a transistor (e.g., 302C, sometimes referred to as a second transistor) operating as a switch for (pre-) charging the second access line to the supply voltage according to the gate voltage, for example. In some configurations, the transistor can be a P-channel MOSFET (PMOS) transistor, although other types of transistors can be implemented not limited to the PMOS transistor, such as N-type transistors, etc.

In some implementations, the control line (e.g., 208) can be operatively coupled to the memory controller or other devices capable of sending signals to initiate or terminate the pre-charging of the access lines. The control line may extend, in part, in a second lateral direction (e.g., horizontally as described in conjunction with FIG. 2, or vertically as described in conjunction with FIG. 1) and operatively coupled to at least one of the first pre-charge circuit or the second pre-charge circuit. For example, the memory device can include a first control line extending in the second lateral direction perpendicular to the first lateral direction and operatively coupled to the first pre-charge circuit. The memory device can include a second control line extending in the second lateral direction and operatively coupled to the second pre-charge circuit. The first control line and the second control line can be operatively coupled to each other via a third control line extending in the first lateral direction. In some cases, the first, second, or third control lines can refer to portions or segments of a single control line (e.g., 208).

The signal sent via the control line can be used to initiate or terminate the (pre-) charging of at least one of the first access line or the second access line to the supply voltage. In some cases, the control line can include a buffer and an inverter. For instance, referring to different portions of the control lines, e.g., the first control line operatively coupled to the first pre-charge circuit and the second control line operatively coupled to the second pre-charge circuit, each of the first and second control lines can include a respective buffer and inverter. The first control line can include a first buffer and a first inverter disposed thereof. The second control line can include a second buffer and a second inverter disposed thereof. In such cases, sending a low signal (e.g., VSS or 0V) via the control line can initiate (pre-) charging at least one of the first access line or the second access line to the supply voltage.

In some configurations, the pre-charge circuit can include an equalizer. The equalizer can include or correspond to at least one transistor (e.g., 302A) or switch configured to equalize charging between a pair of access lines to the supply voltage, e.g., equalize the voltages across the BLs. The equalizer can be included with other switches (e.g., transistors 302B, 302C) configured to activate or deactivate pre-charging of the access lines.

For example, each pre-charge circuit can include three transistors, e.g., a first transistor (e.g., 302B), a second transistor (e.g., 302C), and a third transistor (e.g., 302A). Taking the first pre-charge circuit as an example, although similar components can apply for the second pre-charge circuit, the first, second, and third transistors can be operatively coupled between a control line (e.g., 208), the supply voltage (e.g., VDD, sometimes referred to as a power source or a power line), and/or at least one of the access lines. The first transistor can include a first S/D electrode operatively coupled to the first access line, a second electrode S/D electrode operatively coupled to the supply voltage, and a first gate electrode operatively coupled to the control line. The second transistor can include a third S/D electrode operatively coupled to the third access line, a fourth electrode S/D electrode operatively coupled to the supply voltage, and a second gate electrode operatively coupled to the control line. The third transistor can include a fifth S/D electrode operatively coupled to the first access line, a sixth electrode S/D electrode operatively coupled to the third access line, and a third gate electrode operatively coupled to the control line. The third transistor can operate as the equalizer, and the first and second transistors can operate as switches for activating or deactivating the pre-charging. The second pre-charge circuit may include similar components configured for pre-charging the second access line and the fourth access line.

In some configurations, the memory device can include a control transistor (e.g., 402) as part of each pre-charge circuit. The control transistor can be configured to control the supply of power (e.g., from an internal power supply (e.g., VDD)) to one or more components of the pre-charge circuit. For example, the control transistor can be operatively coupled between the supply voltage and each pair of transistors (e.g., 302B, 302C) configured to charge the first access line and the third access line, or the second access line and the fourth access line, to the supply voltage. The control transistor can include a first S/D electrode, a second S/D electrode, and a gate electrode. The first S/D electrode can be coupled to one or more switches (e.g., 302B, 302C). The second S/D electrode can be coupled to the power source (e.g., VDD). The gate electrode can be coupled to a signal line, which may be different from for instance the control line 208. For example, the control transistor can include or be configured as a power-gating feature for allowing or preventing the access line from being pre-charged to the supply voltage. The internal power supply can be configured to (pre-) charge at least one of the pairs of access lines to the supply voltage according to at least the state of the transistor. For example, if the control transistor is in an active state (e.g., activated), a pair of access lines can be pre-charged to the supply voltage, e.g., according to the BLEQB signal for the switches (e.g., 302B, 302C). In another example, if the control transistor is in an inactive state (e.g., deactivated), the pair of access lines may not be pre-charged. The control transistor can be controlled via a signal from the memory controller, for example. The signal for controlling the control transistor (e.g., 402) may be different from the signal for controlling the switches and/or the equalizer (e.g., 302A-C).

In some implementations, the first pre-charge circuit (or the second pre-charge circuit) can include a first transistor (e.g., 702A) and a second transistor (e.g., 702B). Each transistor can include a respective first S/D electrode, second S/D electrode, and gate electrode. For example, the first S/D electrode of the first transistor can be operatively coupled to the first access line. The second S/D electrode of the first transistor can be operatively coupled to a power supply (e.g., VDD). The gate electrode of the first transistor can be operatively coupled to the third access line (e.g., BLB). Further, the first S/D electrode of the second transistor can be operatively coupled to the third access line. The second source/drain electrode of the second transistor can be operatively coupled to the power supply. The gate electrode of the second transistor can be operatively coupled to the first access line. The transistors provided herein can function as part of a cross-P structure, for example. In various arrangements, the memory device discussed herein may include additional or alternative components not limited to those discussed herein for operating with the far end pre-charge circuit.

In one aspect of the present disclosure, a memory circuit is disclosed. The memory circuit includes a memory array comprising a first portion and a second portion, wherein the first portion comprises a plurality of first memory cells, and the second portion comprises a plurality of second memory cells. The memory circuit includes an input/output (I/O) circuit physically disposed next to the memory array along a first lateral direction, wherein the I/O circuit is operatively coupled to the first portion and the second portion through a first access line and a second access line, respectively. The memory circuit includes a first pre-charge circuit physically disposed opposite the first portion from the I/O circuit along the first lateral direction, and configured to charge the first access line to a supply voltage prior to accessing the plurality of first memory cells. The memory circuit includes a second pre-charge circuit physically disposed opposite the second portion from the first pre-charge circuit along the first lateral direction, and configured to charge at least a portion of the second access line to the supply voltage prior to accessing the plurality of second memory cells.

In another aspect of the present disclosure, a memory circuit is disclosed. The memory circuit includes a memory array comprising a first portion and a second portion, wherein the first portion comprises a plurality of first memory cells that are coupled to one another through a first bit line, and the second portion comprises a plurality of second memory cells that are coupled to one another through a second bit line, and wherein the first bit line extends along a first lateral direction and the second bit line includes at least a portion extending along the first lateral direction. The memory circuit includes a first pre-charge circuit physically disposed next to the first portion along the first lateral direction, wherein the first pre-charge circuit is configured to charge the first bit line to a logic high state prior to accessing the plurality of first memory cells. The memory circuit includes a second pre-charge circuit physically disposed next to the second portion along the first lateral direction, wherein the second pre-charge circuit is configured to charge the second bit line to the logic high state prior to accessing the plurality of second memory cells.

In yet another aspect of the present disclosure, a method for forming a memory device is disclosed. The method includes forming a memory array comprising a first portion and a second portion, wherein the first portion comprises a plurality of first memory cells, and the second portion comprises a plurality of second memory cells. The method includes forming an input/output (I/O) circuit physically disposed next to the memory array along a first lateral direction, wherein the I/O circuit is operatively coupled to the first portion and the second portion through a first access line and a second access line, respectively. The method includes forming a first pre-charge circuit physically disposed opposite the first portion from the I/O circuit along the first lateral direction, and configured to charge the first access line to a supply voltage prior to accessing the plurality of first memory cells. The method includes forming a second pre-charge circuit physically disposed opposite the second portion from the first pre-charge circuit along the first lateral direction, and configured to charge at least a portion of the second access line to the supply voltage prior to accessing the plurality of second memory cells.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

I foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory circuit, comprising:
a memory array comprising a first portion and a second portion, wherein the first portion comprises a plurality of first memory cells, and the second portion comprises a plurality of second memory cells;
an input/output (I/O) circuit physically disposed next to the memory array along a first lateral direction, wherein the I/O circuit is operatively coupled to the first portion and the second portion through a first access line and a second access line, respectively;
a first pre-charge circuit physically disposed opposite the first portion from the I/O circuit along the first lateral direction, and configured to charge the first access line to a supply voltage prior to accessing the plurality of first memory cells; and
a second pre-charge circuit physically disposed opposite the second portion from the first pre-charge circuit along the first lateral direction, and configured to charge at least a portion of the second access line to the supply voltage prior to accessing the plurality of second memory cells.

2. The memory circuit of claim 1, comprising:
a first control line extending in a second lateral direction perpendicular to the first lateral direction and operatively coupled to the first pre-charge circuit;
a second control line extending in the second lateral direction and operatively coupled to the second pre-charge circuit,
wherein the first control line is operatively coupled to the second control line via a third control line extending in the first lateral direction.

3. The memory circuit of claim 2, further comprising:
a first buffer disposed in the first control line;
a first inverter disposed in the first control line;
a second buffer disposed in the second control line; and
a second inverter disposed in the second control line.

4. The memory circuit of claim 1, wherein at least one of:
the first pre-charge circuit comprises a first transistor operating as a switch for charging the first access line to the supply voltage according to a gate voltage; or
the second pre-charge circuit comprises a second transistor operating as a switch for charging the second access line to the supply voltage according to a gate voltage.

5. The memory circuit of claim 4, wherein the first and second transistors are each a P-channel MOSFET (PMOS) transistor.

6. The memory circuit of claim 1, wherein the I/O circuit is operatively coupled to the first portion through the first access line and a third access line, and wherein the I/O circuit is operatively coupled to the second portion through the second access line and a fourth access line.

7. The memory circuit of claim 6, wherein at least one of:
the first pre-charge circuit comprises:
a first transistor comprising a first source/drain electrode operatively coupled to the first access line, a second source/drain electrode operatively coupled to the supply voltage, and a first gate electrode operatively coupled to a control line;
a second transistor comprising a third source/drain electrode operatively coupled to the third access line, a fourth source/drain electrode operatively coupled to the supply voltage, and a second gate electrode operatively coupled to the control line; and
a third transistor comprising a fifth source/drain electrode operatively coupled to the first access line, a sixth source/drain electrode operatively coupled to the third access line, and a third gate electrode operatively coupled to the control line; or
the second pre-charge circuit comprises:
a first transistor comprising a first source/drain electrode operatively coupled to the second access line, a second source/drain electrode operatively coupled to the supply voltage, and a first gate electrode operatively coupled to a control line;
a second transistor comprising a third source/drain electrode operatively coupled to the fourth access line, a fourth source/drain electrode operatively coupled to the supply voltage, and a second gate electrode operatively coupled to the control line; and
a third transistor comprising a fifth source/drain electrode operatively coupled to the second access line, a sixth source/drain electrode operatively coupled to the fourth access line, and a third gate electrode operatively coupled to the control line.

8. The memory circuit of claim 6, further comprising:
a control transistor operatively coupled between the supply voltage and each pair of transistors configured to charge the first access line and the third access line, or the second access line and the fourth access line, to the supply voltage.

9. The memory circuit of claim 1, wherein the first access line extends from the I/O circuit to the first pre-charge circuit and is disposed in a first metallization layer, and the second access line extends from the I/O circuit to the second pre-charge circuit and includes a first segment and a second segment, in which the first segment is disposed in a second metallization layer and the second segment is disposed in the first metallization layer.

10. The memory circuit of claim 9, wherein the second metallization layer is disposed above the first metallization layer.

11. The memory circuit of claim 1, wherein the first pre-charge circuit comprises a first transistor and a second transistor,
wherein a first source/drain electrode of the first transistor is operatively coupled to the first access line, a second source/drain electrode of the first transistor is operatively coupled to a power supply, and a gate electrode of the first transistor is operatively coupled to a third access line, and
wherein a first source/drain electrode of the second transistor is operatively coupled to the third access line, a second source/drain electrode of the second transistor is operatively coupled to the power supply, and a gate electrode of the second transistor is operatively coupled to the first access line.

12. A memory circuit, comprising:
a memory array comprising a first portion and a second portion, wherein the first portion comprises a plurality of first memory cells that are coupled to one another through a first bit line, and the second portion comprises a plurality of second memory cells that are coupled to one another through a second bit line, and wherein the first bit line extends along a first lateral direction and the second bit line includes at least a portion extending along the first lateral direction;
a first pre-charge circuit physically disposed next to the first portion along the first lateral direction, wherein the first pre-charge circuit is configured to charge the first bit line to a logic high state prior to accessing the plurality of first memory cells; and
a second pre-charge circuit physically disposed next to the second portion along the first lateral direction, wherein the second pre-charge circuit is configured to charge the second bit line to the logic high state prior to accessing the plurality of second memory cells.

13. The memory circuit of claim 12, wherein the first bit line extends to the first pre-charge circuit and is disposed in a first metallization layer, and the second bit line extends to the second pre-charge circuit and includes a first segment and a second segment, in which the first segment is disposed in a second metallization layer and the second segment is disposed in the first metallization layer.

14. The memory circuit of claim 13, wherein the second metallization layer is disposed above the first metallization layer.

15. The memory circuit of claim 12, comprising:
a first control line extending in a second lateral direction perpendicular to the first lateral direction and operatively coupled to the first pre-charge circuit;
a second control line extending in the second lateral direction and operatively coupled to the second pre-charge circuit,
wherein the first control line is operatively coupled to the second control line via a third control line extending in the first lateral direction.

16. The memory circuit of claim 15, further comprising:
a first buffer disposed in the first control line;
a first inverter disposed in the first control line;
a second buffer disposed in the second control line; and
a second inverter disposed in the second control line.

17. The memory circuit of claim 12, wherein at least one of:
the first pre-charge circuit comprises a first transistor operating as a switch for charging the first bit line to the logic high state according to a gate voltage; or
the second pre-charge circuit comprises a second transistor operating as a switch for charging the second bit line to the logic high state according to a gate voltage.

18. A method for forming a memory device, comprising:
forming a memory array comprising a first portion and a second portion, wherein the first portion comprises a plurality of first memory cells, and the second portion comprises a plurality of second memory cells;
forming an input/output (I/O) circuit physically disposed next to the memory array along a first lateral direction, wherein the I/O circuit is operatively coupled to the first portion and the second portion through a first access line and a second access line, respectively;
forming a first pre-charge circuit physically disposed opposite the first portion from the I/O circuit along the first lateral direction, and configured to charge the first access line to a supply voltage prior to accessing the plurality of first memory cells; and
forming a second pre-charge circuit physically disposed opposite the second portion from the first pre-charge circuit along the first lateral direction, and configured to charge at least a portion of the second access line to the supply voltage prior to accessing the plurality of second memory cells.

19. The method of claim 18, comprising:
forming a third access line physically extending along the first lateral direction and operatively coupled to the first portion, the I/O circuit, and the first pre-charge circuit; and
forming a fourth access line physically extending along the first lateral direction and operatively coupled to the second portion, the I/O circuit, and the second pre-charge circuit.

20. The method of claim 19, wherein at least one of:
the first pre-charge circuit comprises:
a first transistor comprising a first source/drain electrode operatively coupled to the first access line, a second source/drain electrode operatively coupled to the supply voltage, and a first gate electrode operatively coupled to a control line;
a second transistor comprising a third source/drain electrode operatively coupled to the third access line, a fourth source/drain electrode operatively coupled to the supply voltage, and a second gate electrode operatively coupled to the control line; and
a third transistor comprising a fifth source/drain electrode operatively coupled to the first access line, a sixth source/drain electrode operatively coupled to the third access line, and a third gate electrode operatively coupled to the control line; or
the second pre-charge circuit comprises:
a first transistor comprising a first source/drain electrode operatively coupled to the second access line, a second source/drain electrode operatively coupled to the supply voltage, and a first gate electrode operatively coupled to a control line;
a second transistor comprising a third source/drain electrode operatively coupled to the fourth access line, a fourth source/drain electrode operatively coupled to the supply voltage, and a second gate electrode operatively coupled to the control line; and
a third transistor comprising a fifth source/drain electrode operatively coupled to the second access line, a sixth source/drain electrode operatively coupled to the fourth access line, and a third gate electrode operatively coupled to the control line.
